(19) United States
(12) Patent Application Publication
(10) Pub. No.: US 2024/0178255 A1
(43) Pub. Date: May 30, 2024

(54) IMAGE SENSOR

(71) Applicant: SAMSUNG ELECTRONICS CO., LTD., SUWON-SI (KR)

(72) Inventors: Dae Hoon KIM, Suwon-si (KR); Yong Jun KIM, Suwon-si (KR)

(21) Appl. No.: 18/373,353

(22) Filed: Sep. 27, 2023

(30) Foreign Application Priority Data
Nov. 30, 2022 (KR) 10-2022-0164770

(51) Int. Cl. H01L 27/146; H01L 23/00

(52) U.S. Cl. CPC H01L 27/14634; H01L 24/08; H01L 24/80; H01L 27/14621; H01L 27/14627; H01L 27/1463; H01L 27/14636; H01L 27/14645; H01L 27/1469; H01L 2224/08145; H01L 2224/80895; H01L 2224/80896

(57) ABSTRACT

An image sensor includes a first substrate having a photoelectric conversion element. A first gate electrode is on a first side of the first substrate. A floating diffusion region is in the first substrate. A first wiring structure is on the first side and includes a first wiring layer and a first bonding pad. A second substrate has a third side that includes second and third gate electrodes. An impurity region is in the second substrate. A second wiring structure is on the third side and includes a second wiring layer and a second bonding pad directly contacting the first bonding pad. A fourth gate electrode is on a fourth side of the second substrate. A third wiring structure is on the fourth side and includes a third wiring layer. The floating diffusion region is connected to the impurity region through the first wiring structure and the second wiring structure.

### CROSS-REFERENCE TO RELATED APPLICATION

This application claims priority under 35 U.S.C. § 119 to Korean Patent Application No. 10-2022-0164770, filed on Nov. 30, 2022 in the Korean Intellectual Property Office, the disclosure of which is incorporated by reference in its entirety herein.

### 1. TECHNICAL FIELD

The present disclosure relates to an image sensor.

### 2. DISCUSSION OF RELATED ART

An image sensor is a semiconductor device that converts optical information into an electric signal. Image sensors may include a charged coupled device (CCD) image sensor and a complementary metal-oxide semiconductor (CMOS) image sensor.

The image sensor may be arranged in the form of a package. The package may be protect the image sensor and allow light to enter a photo-receiving surface or a sensing area of the image sensor.

### SUMMARY

Aspects of the present disclosure provide an image sensor having increased product reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, an image sensor includes a first substrate that includes a first side and a second side opposite to each other in a first direction. A photoelectric conversion element is in the first substrate. A first gate electrode is on the first side of the first substrate and positioned adjacent to the photoelectric conversion element. A floating diffusion region is in the first substrate on one side of the first gate electrode. A first wiring structure is on the first side of the first substrate. The first wiring structure includes a first wiring layer and a first bonding pad on the first wiring layer. A second substrate includes a third side opposite to the first side and a fourth side opposite to the third side. Second and third gate electrodes are spaced apart from each other on the third side of the second substrate. An impurity region is in the second substrate on one side of the second gate electrode. A second wiring structure is on the third side of the second substrate. The second wiring structure includes a second wiring layer and a second bonding pad on the second wiring layer. A fourth gate electrode is on the fourth side of the second substrate. A third wiring structure is on the fourth side of the second substrate. The third wiring structure includes a third wiring layer. The second bonding pad directly contacts the first bonding pad. The floating diffusion region is connected to the impurity region through the first wiring structure and the second wiring structure.

According to an embodiment of the present disclosure, an image sensor comprising a first semiconductor chip and a second semiconductor chip having a plurality of pixel groups positioned therein. The first and second semiconductor chips are stacked in a first direction. The first semiconductor chip includes a first substrate that includes a first side and a second side opposite to each other in the first direction. A first pixel is on the first side of the first substrate. The first pixel includes a first photoelectric conversion element in the first substrate and a first-1 transistor. A second pixel is on the first side of the first substrate. The second pixel includes a second photoelectric conversion element in the first substrate and a first-2 transistor. A third pixel is on the first side of the first substrate. The third pixel includes a third photoelectric conversion element in the first substrate and a first-3 transistor. A fourth pixel is on the first side of the first substrate. The fourth pixel includes a fourth photoelectric conversion element in the first substrate and a first-4 transistor. A floating diffusion region is connected to the first-1 to first-4 transistors in the first substrate. The floating diffusion region is disposed between the first to fourth pixels. A first wiring structure is on the first side of the first substrate. The first wiring structure includes a first wiring layer. The second semiconductor chip includes a second substrate including a third side opposite to the first side, and a fourth side opposite to the third side. A second wiring structure is on the third side of the second substrate. The second wiring structure includes a second wiring layer. Second and third transistors are on the third side of the second substrate. The second and third transistors are spaced apart from each other. A fourth transistor is on the fourth side of the second substrate. A third wiring structure is on the fourth side of the second substrate. The third wiring structure includes a third wiring layer. Each plurality of pixel groups includes the first to fourth pixels, the floating diffusion region, and the second to fourth transistors.

According to an embodiment of the present disclosure, an image sensor includes a first substrate that includes a first side and a second side opposite to each other in a first direction. A color filter is on the second side of the first substrate. A microlens is on the color filter. A photoelectric conversion element is inside the first substrate. A first gate electrode is on the first side of the first substrate. The first gate electrode is positioned adjacent to the photoelectric conversion element. A floating diffusion region is in the first substrate on one side of the first gate electrode. A first wiring structure is on the first side of the first substrate. The first wiring structure includes a first wiring layer and a first bonding pad on the first wiring layer. A second substrate includes a third side opposite to the first side and a fourth side opposite to the third side. Second and third gate electrodes are on the third side of the second substrate. The second and third gate electrodes are spaced apart from each other. An impurity region is inside the second substrate on one side of the second gate electrode. A second wiring structure is on the third side of the second substrate. The second wiring structure includes a second wiring layer and a second bonding pad on the second wiring layer. The second bonding pad directly contacts the first bonding pad. A fourth gate electrode is on the fourth side of the second substrate. A third wiring structure is on the fourth side of the second substrate. The third wiring structure includes a third wiring layer, a contact penetrating the second substrate and connected to the second wiring layer and the third wiring layer, and a third bonding pad on the third wiring layer. A third substrate includes a fifth side opposite to the fourth side. A fifth gate electrode is on the fifth side of the third substrate. A fourth wiring structure is on the fifth side of the third substrate. The fourth wiring structure includes a fourth wiring layer and a fourth bonding pad on the fourth wiring layer. The first bonding pad directly contacts the second bonding pad. The third bonding pad directly contacts the fourth bonding pad. The floating diffusion region is connected to the impurity region and the third gate electrode through the first wiring structure and the second wiring structure.

### BRIEF DESCRIPTION OF THE DRAWINGS

The above and other aspects and features of the present disclosure will become more apparent by explaining in detail embodiments thereof with reference to the attached drawings, in which:

FIG. 1 is a block diagram of an image sensing device according to an embodiment of the present disclosure;

FIG. 2 is a circuit diagram for explaining a pixel of an image sensor according to an embodiment of the present disclosure;

FIG. 3 is a perspective view of an image sensor according to an embodiment of the present disclosure;

FIG. 4 is a layout diagram of the image sensor according to an embodiment of the present disclosure;

FIGS. 5 to 7 are enlarged views of a region R of FIG. 4 according to embodiments of the present disclosure;

FIG. 8 is a cross-sectional view taken along a line A-A′ of FIGS. 5 to 7 according to an embodiment of the present disclosure;

FIG. 9 is an enlarged view of the region R of FIG. 4 according to an embodiment of the present disclosure;

FIG. 10 is a cross-sectional view taken along a line A-A′ of FIG. 9 according to an embodiment of the present disclosure;

FIG. 11 is a circuit diagram for explaining a pixel of the image sensor according to an embodiment of the present disclosure;

FIGS. 12 and 13 are enlarged views of the region R of FIG. 4 according to embodiments of the present disclosure;

FIG. 14 is a cross-sectional view taken along a line A-A′ of FIGS. 5, 12 and 13 according to an embodiment of the present disclosure;

FIG. 15 is an enlarged view of the region R of FIG. 4 according to an embodiment of the present disclosure; and

FIGS. 16 to 19 are intermediate stage diagrams for explaining a method for manufacturing the image sensor according to embodiments of the present disclosure.

### DETAILED DESCRIPTION OF EMBODIMENTS

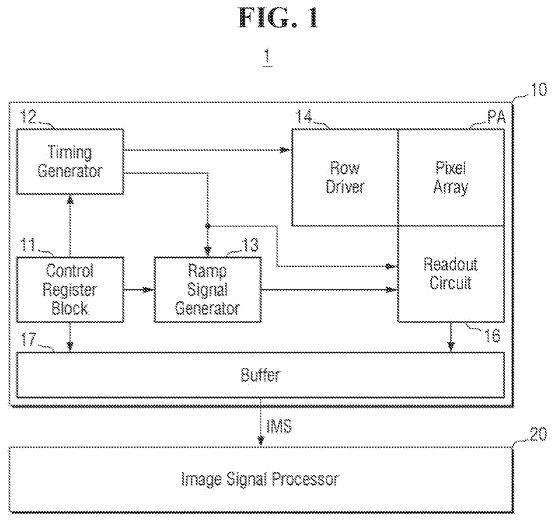

FIG. 1 is a block diagram of an image sensing device according to some embodiments.

Referring to FIG. 1, an image sensing device 1 according to some embodiments may include an image sensor 10 and an image signal processor 20.

In an embodiment, the image sensor 10 may generate an image signal IMS, by sensing an image to be sensed using light. In some embodiments, the generated image signal IMS may be, for example, a digital signal. However, embodiments of the present disclosure are not necessarily limited thereto.

The image signal IMS may be provided to the image signal processor 20 and processed by the image signal processor 20. In an embodiment, the image signal processor 20 receives the image signal IMS that is output from a buffer 17 of the image sensor 10, and may process or treat the received image signal IMS to easily display the image signal

In some embodiments, the image signal processor 20 may perform digital binning on the image signal IMS that is output from the image sensor 10. The image signal IMS that is output from the image sensor 10 may be a raw image signal from the pixel array PA without analog binning or may be the image signal IMS on which the analog binning has already been performed.

In some embodiments, the image sensor 10 and the image signal processor 20 may be positioned separately from each other as shown. For example, the image sensor 10 may be mounted on a first chip and the image signal processor 20 may be mounted on a second chip. In this embodiment, the image sensor 10 and the image signal processor 20 may communicate with each other through a predetermined interface. However, embodiments of the present disclosure are not necessarily limited thereto. For example, in an embodiment the image sensor 10 and the image signal processor 20 may be implemented as a single package, for example, a MCP (multi-chip package).

In an embodiment, the image sensor 10 may include a pixel array PA, a control register block 11, a timing generator 12, a row driver 14, a readout circuit 16, a ramp signal generator 13, and a buffer 17.

The control register block 11 may generally control the operation of the image sensor 10. For example, the control register block 11 may directly transmit an operating signal to the timing generator 12, the ramp signal generator 13, and the buffer 17.

The timing generator 12 may generate a signal that serves as a reference for the operating timing of various components of the image sensor 10. An operating timing reference signal generated by the timing generator 12 may be sent to the ramp signal generator 13, the row driver 14, the readout circuit 16, and the like.

The ramp signal generator 13 may generate and transmit the ramp signal that is used in the readout circuit 16. For example, in an embodiment the readout circuit 16 may include a correlated double sampler (CDS), a comparator, or the like. The ramp signal generator 13 may generate and transmit the ramp signal that is used in the correlated double sampler, the comparator, or the like.

The row driver 14 may selectively activate the rows of the pixel array PA.

The pixel array PA may sense an external image. In an embodiment, the pixel array PA may include a plurality of pixels that are arranged two-dimensionally (e.g., in the form of a matrix).

In an embodiment, the readout circuit 16 may sample the pixel signal provided from the pixel array PA, compare the pixel signal with the ramp signal, and then convert an analog image signal (e.g., data) into a digital image signal (e.g., data) on the basis of the comparison results

The buffer 17 may include, for example, a latch. The buffer 17 may temporarily store the image signal IMS to be provided to the outside, and may transmit the image signal IMS to an external memory or an external device.

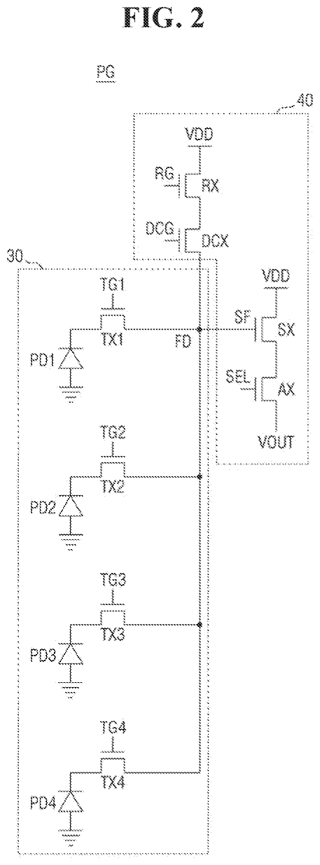

FIG. 2 is a circuit diagram for explaining the pixel of the image sensor according to some embodiments.

Referring to FIGS. 1 and 2, the pixel array PA according to some embodiments may include a plurality of pixel groups PG.

In an embodiment, the pixel group PG includes first to fourth photoelectric conversion elements PD1, PD2, PD3, and PD4, first to fourth transfer transistors TX1, TX2, TX3, and TX4, a floating diffusion region FD, a dual conversion gain transistor DCX, a reset transistor RX, a source follower transistor SX, and a selection transistor AX. The first to fourth photoelectric conversion elements PD1, PD2, PD3 and PD4 may share the floating diffusion region FD, the dual conversion gain transistor DCX, the reset transistor RX, the source follower transistor SX, and the selection transistor AX.

Each of the first to fourth photoelectric conversion elements PD1, PD2, PD3, and PD4 may generate electric charges in proportion to the amount of light incident from the outside.

The first to fourth transfer transistors TX1, TX2, TX3 and TX4 may include the first to fourth transfer gate electrodes TG1, TG2, TG3 and TG4, respectively. Sources of the first to fourth transfer transistors TX1, TX2, TX3, and TX4 may be connected to the first to fourth photoelectric conversion elements PD1, PD2, PD3, and PD4, respectively, and drains of each of the first to fourth transfer transistors TX1, TX2, TX3, and TX4 may be connected to the floating diffusion region FD. For example, the first to fourth transfer transistors TX1, TX2, TX3, and TX4 may share the floating diffusion region FD as a drain. Electric charges generated by the respective first to fourth photoelectric conversion elements PD1, PD2, PD3 and PD4 are transmitted to the floating diffusion region FD by the respective first to fourth transfer transistors TX1, TX2, TX3 and TX4, and may be accumulated in the floating diffusion region FD. The floating diffusion region FD is a region for switching the electric charges to voltage, and has a parasitic capacitance, and the electric charges may be accumulatively stored.

The source follower transistor SX including the source follower gate electrode SF amplifies the change in electric potential of the floating diffusion region FD that has received the electric charges from the first to fourth photoelectric conversion elements PD1, PD2, PD3, and PD4, and outputs it to an output line VOUT. The source follower gate electrode SF may be connected to the floating diffusion region FD. In an embodiment, the drain of the source follower transistor SX may be connected to the power supply voltage VDD, and the source of the source follower transistor SX may be connected to the drain of the selection transistor AX. When the source follower transistor SX is turned on, the power supply voltage VDD supplied to the drain of the source follower transistor SX may be sent to the drain of the selection transistor AX.

The selection transistor AX including the selection gate electrode SEL may select a pixel to be read in units of a row. When the selection transistor AX is turned on, the power supply voltage VDD connected to the drain of the selection transistor AX may be sent to the output line VOUT.

The dual conversion gain transistor DCX may adjust a conversion gain. In an embodiment, the drain of the dual conversion gain transistor DCX may be connected to the source of the reset transistor RX, and the source of the dual conversion gain transistor DCX may be connected to the floating diffusion region FD. In an embodiment, the dual conversion gain transistor DCX including the dual conversion gain gate electrode DCG may be, for example, turned on in a high illumination mode, and turned off in a low illumination mode.

The reset transistor RX including the reset gate electrode RG may periodically reset the floating diffusion region FD. When the reset transistor RX and the dual conversion gain transistor DCX are turned on, the power supply voltage VDD supplied to the drain of the reset transistor RX may be sent to the floating diffusion region FD.

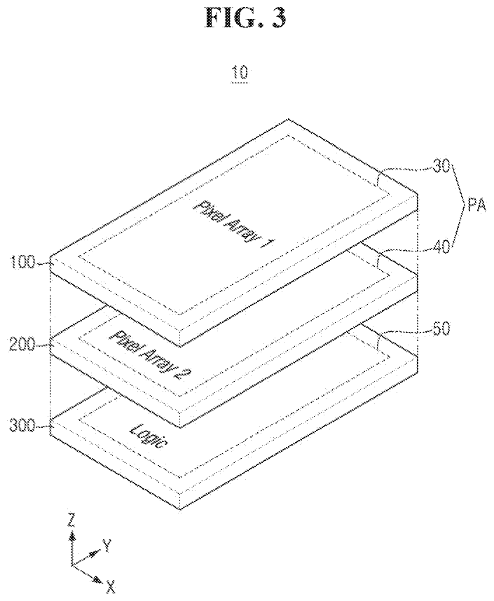

FIG. 3 is a perspective view of an image sensor according to some embodiments.

Referring to FIGS. 1 to 3, an image sensor 10 according to some embodiments may include a first semiconductor chip 100, a second semiconductor chip 200, and a third semiconductor chip 300 that are stacked in order (e.g., consecutively stacked in a third direction Z). The first semiconductor chip 100 may be disposed above the second semiconductor chip 200, and the second semiconductor chip 200 may be disposed above the third semiconductor chip 300. The first semiconductor chip 100 may be called an upper board, the second semiconductor chip 200 may be called a middle board, and the third semiconductor chip 300 may be called a lower board. Hereinafter, the upper surface, the lower surface, the upper side, and the lower side may be based on the third direction Z.

The first semiconductor chip 100 and the second semiconductor chip 200 may include a pixel array PA. The pixel array PA may include a first pixel array 30 and a second pixel array 40. For example, the first semiconductor chip 100 may include the first pixel array 30, and the second semiconductor chip 200 may include the second pixel array 40. In an embodiment, the first pixel array 30 may include first to fourth pixels PX1, PX2, PX3, and PX4 and a floating diffusion region FD. The second pixel array 40 may include a dual conversion gain transistor DCX, a reset transistor RX, a source follower transistor SX, and a selection transistor AX.

In an embodiment, the third semiconductor chip 300 may include a logic region 50 in which logic elements are disposed. The logic elements included in the logic region 50 are electrically connected to the pixel array PA, and may provide signals to the pixels or process signals output from the pixels. In an embodiment, the logic region 50 may include, for example, a control register block 11, a timing generator 12, a ramp signal generator 13, a row driver 14, a readout circuit 16, and the like.

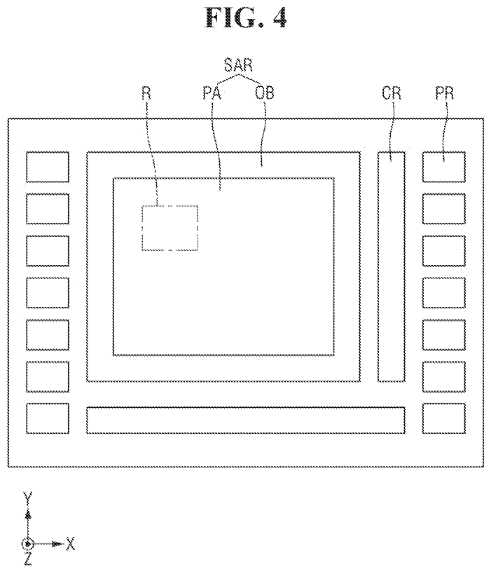

FIG. 4 is a layout diagram of an image sensor according to some embodiments.

Referring to FIG. 4, the image sensor according to some embodiments may include a sensor array region SAR, a connecting region CR, and a pad region PR.

The sensor array region SAR may include a region corresponding to the pixel array PA of FIG. 1. The sensor array region SAR may include a pixel array PA and a light shielding region OB. The active pixels that receive light to generate an active signal may be arranged in the pixel array PA. The optical black pixels that block light and generate optical black signals may be arranged in the light shielding region OB. The light shielding region OB may be formed, for example, along the periphery of the pixel array PA. For example, in an embodiment, the light shielding region OB may completely surround the pixel array PA (e.g., in the X and Y directions). However, embodiments of the present disclosure are not necessarily limited thereto. In some embodiments, dummy pixels may be formed in the pixel array PA adjacent to the light shielding region OB.

The connecting region CR may be formed around the sensor array region SAR. For example, the connecting region CR may be formed on one side of the sensor array region SAR. For example, in an embodiment shown in FIG. 4 the connecting region CR is formed on the right side of the sensor region SAR (e.g., in the X direction). However, embodiments of the present disclosure are not necessarily limited thereto. Wirings may be formed in the connecting region CR, and may be configured to transmit and receive electrical signals of the sensor array region SAR.

The pad region PR may be formed around the sensor array region SAR. For example, the pad region PR may be formed to be adjacent to at least one edge of the image sensor according to some embodiments. The pad region PR may be connected to an external device or the like, and may be configured to transmit and receive electrical signals between the image sensor and the external device.

Although the connecting region CR is shown as being interposed between the sensor array region SAR and the pad region PR, this is merely an example. The positioning of the sensor array region SAR, the connecting region CR and the pad region PR may vary in some embodiments.

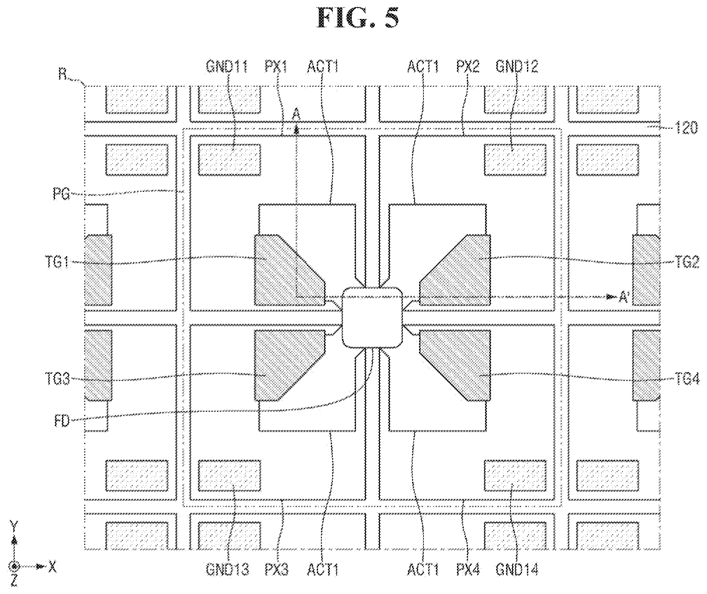

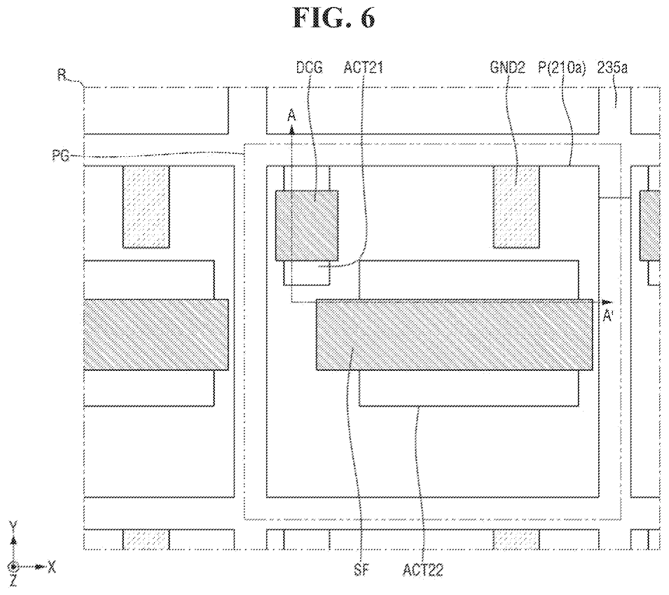

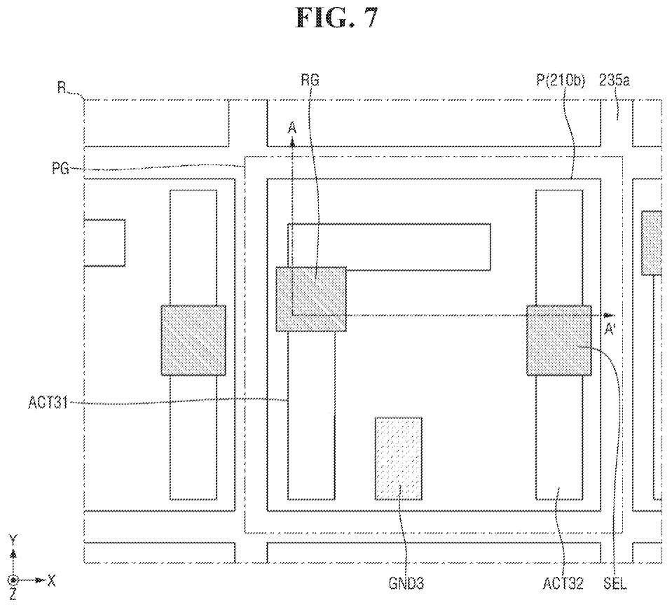

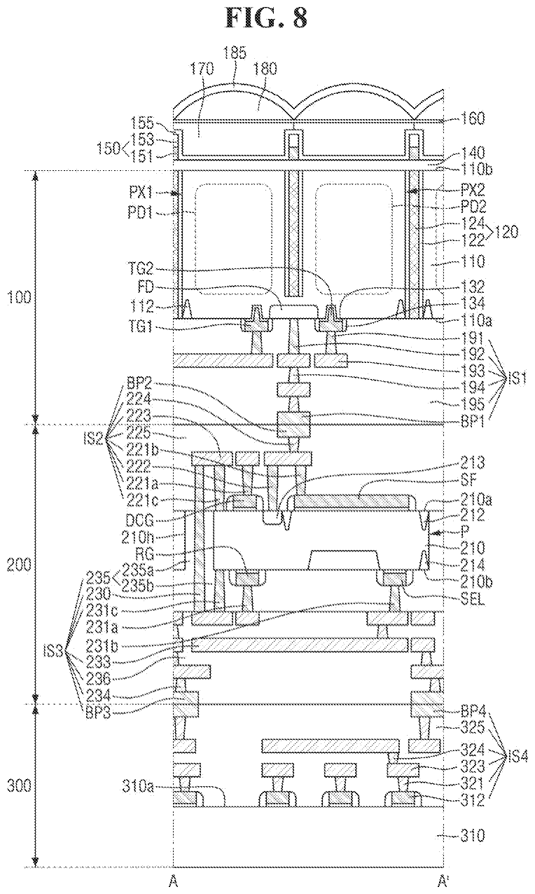

FIGS. 5 to 7 are enlarged views of the region R of FIG. 4. FIG. 8 is a cross-sectional view taken along a line A-A′ of FIGS. 5 to 7. FIG. 5 is an enlarged view of the region R on the first substrate 110 of the first semiconductor chip 100, FIG. 6 is an enlarged view of the region R on the third side 210a of the second substrate 210 of the second semiconductor chip 200, and FIG. 7 is an enlarged view of the region R on the fourth side 210b of the second substrate 210 of the second semiconductor chip 200.

Referring to FIGS. 2 and 5 to 8, the pixel array PA of the image sensor according to some embodiments may include a plurality of pixel groups PG. In an embodiment, the plurality of pixel groups PG may include the first to fourth pixels PX1, PX2, PX3, and PX4, the floating diffusion region FD, the dual conversion gain transistor DCX, the reset transistor RX, the source follower transistor SX, and the selection transistor AX. Each of the first to fourth pixels PX1, PX2, PX3 and PX4 may include respective first to fourth photoelectric conversion elements PD1, PD2, PD3 and PD4 and respective first to fourth transfer transistors TX1, TX2, TX3 and TX4.

The image sensor according to some embodiments may include a first substrate 110, a floating diffusion region FD, a pixel isolation pattern 120, first to fourth photoelectric conversion elements PD1, PD2, PD3, and PD4, and first to fourth transfer gate electrodes TG1, TG2, TG3, and TG4, a first insulating layer 140, a grid pattern 150, a first protective layer 155, a second insulating layer 160, a color filter 170, a microlens 180, a second protective layer 185, a dual conversion gain gate electrode DCG, a source follower gate electrode SF, a reset gate electrode RG, a selection gate electrode SEL, a second substrate 210, a third substrate 310, and first to fourth wiring structures IS1, IS2, IS3 and IS4.

The first substrate 110 may include a first side 110a and a second side 110b that are opposite to each other (e.g., in the Z direction). The first side 110a may be called a front side of the first substrate 110, and the second side 110b may be called a back side of the first substrate 110. In an embodiment, the first and second directions X and Y may intersect each other, and may be parallel to the first side 110a of the first substrate 110. The third direction Z may intersect the first and second directions X and Y, and may be perpendicular to the first side 110a of the first substrate 110.

In some embodiments, the second side 110b of the first substrate 110 may be a photo receiving surface on which light is incident. For example, an image sensor according to some embodiments may be a back illuminated (BSI) image sensor.

The first substrate 110 may be a semiconductor substrate. For example, in an embodiment the first substrate 110 may be bulk silicon or SOI (silicon-on-insulator). In some embodiments, the first substrate 110 may be a silicon substrate or may include other substances, for example, silicon germanium, indium antimonide, lead tellurium compounds, indium arsenic, indium phosphide, gallium arsenide or gallium antimonide. However, embodiments of the present disclosure are not necessarily limited thereto. Alternatively, the first substrate 110 may have an epitaxial layer formed on a base substrate.

A pixel array of an image sensor according to some embodiments may include a plurality of pixel groups PG arranged two-dimensionally (e.g., in the form of matrix) in a plane including the first direction X and the second direction Y.

In an embodiment, the pixel group PG may include first to fourth pixels PX1, PX2, PX3, and PX4 that are adjacent to each other. For example, a first pixel PX1 may be adjacent to a third pixel PX3 in the second direction Y, a second pixel PX2 may be adjacent to the first pixel PX1 in the first direction X and may be adjacent to the fourth pixel PX4 in the second direction Y, and the fourth pixel PX4 may be adjacent to the third pixel PX3 in the first direction X. The first to fourth pixels PX1, PX2, PX3, and PX4 may be arranged in two rows and two columns.

The first to fourth pixels PX1, PX2, PX3, and PX4 may be formed on the first substrate 110. The first to fourth photoelectric conversion elements PD1, PD2, PD3 and PD4 may be disposed in the first substrate 110 of the first to fourth pixels PX1, PX2, PX3 and PX4, respectively. For example, the first substrate 110 may include p-type impurities (e.g., boron (B)), and the first to fourth photoelectric conversion elements PD1, PD2, PD3, and PD4 may be formed by ion-implantation of n-type impurities (e.g., phosphorus (P) or arsenic (As)) into the p-type first substrate 110. Hereinafter, an embodiment in which the first substrate 110 includes p-type impurities will be described for convenience of explanation.

In the image sensor according to some embodiments, each of the first to fourth pixels PX1, PX2, PX3, and PX4 may include a first active region ACT1 and a first ground region GND1.

A first element isolation layer 112 may be disposed in the first substrate 110. For example, the first element isolation layer 112 may be formed by burying an insulating material in a shallow trench formed by patterning the first substrate 110. The first element isolation layer 112 may extend from the first side 110a of the first substrate 110 towards the second side 110b, and a upper surface of the first element isolation layer 112 may be positioned in the first substrate 110. The first element isolation layer 112 may surround each of the first active region ACT1 and the first ground region GND1. Accordingly, the first element isolation layer 112 may define a first active region ACT1 and a first ground region GND1.

In an embodiment, the first ground region GND1 is formed by ion-implantation of P-type impurities of high-concentration into the first substrate 110.

The floating diffusion region FD may be positioned between the first to fourth pixels PX1, PX2, PX3 and PX4. The first to fourth pixels PX1, PX2, PX3 and PX4 may surround the floating diffusion region FD. The floating diffusion region FD may be disposed inside the first substrate 110. The floating diffusion region FD may be positioned inside the first active region ACT1. The floating diffusion region FD may be positioned inside the first side 110a of the first substrate 110. In an embodiment, the floating diffusion region FD may be formed by ion-implantation of n-type impurities into the first substrate 110.

The pixel isolation pattern 120 may separate the first to fourth pixels PX1, PX2, PX3, and PX4. The pixel isolation pattern 120 may surround at least a portion of the first to fourth pixels PX1, PX2, PX3, and PX4 and a portion of the floating diffusion region FD from a planar viewpoint.

For example, the pixel isolation pattern 120 may be formed by burying an insulating material in a deep trench formed by patterning the first substrate 110. The pixel isolation pattern 120 may pass through the first substrate 110 except for a region that overlaps the floating diffusion region FD in the third direction Z. The pixel isolation pattern 120 may be spaced apart from the floating diffusion region FD in the third direction Z. The pixel isolation pattern 120 may overlap the floating diffusion region FD in the third direction Z. For example, the pixel isolation pattern 120 may extend from the second side 110b toward the first side 110a and may terminate away from the first side 110a and spaced apart from the floating diffusion region FD (e.g., in the third direction Z).

The pixel isolation pattern 120 may include a filling pattern 124 and a spacer layer 122. In an embodiment, the filling pattern 124 may include, but is not necessarily limited to, a conductive material, for example, polysilicon (poly Si). The spacer layer 122 may extend along the side surfaces of the filling pattern 124. In an embodiment, the spacer layer 122 may include an insulating material, for example, but is not necessarily limited to, at least one of silicon oxide, aluminum oxide, tantalum oxide, and combinations thereof. The spacer layer 122 may be interposed between the filling pattern 124 and the first substrate 110 to electrically separate the filling pattern 124 and the first substrate 110 from each other.

The first to fourth transfer transistors TX1, TX2, TX3, and TX4 may be positioned on the first side 110a of the first substrate 110. The first to fourth transfer gate electrodes TG1, TG2, TG3 and TG4 may be positioned on the first side 110a of the first substrate 110. The first to fourth transfer gate electrodes TG1, TG2, TG3 and TG4 may be positioned on the first active region ACT1 of the first to fourth pixels PX1, PX2, PX3 and PX4, respectively. The first to fourth transfer gate electrodes TG1, TG2, TG3 and TG4 may be adjacent to (e.g., in the third direction Z) the first to fourth photoelectric conversion elements PD1, PD2, PD3 and PD4, respectively.

The floating diffusion region FD may be positioned in the first active region ACT1 between the first to fourth transfer gate electrodes TG1, TG2, TG3 and TG4. For example, the floating diffusion region FD may be positioned in the first substrate 110 on one side of each of the first to fourth transfer gate electrodes TG1, TG2, TG3 and TG4.

The floating diffusion region FD may overlap the second substrate 210 in the third direction Z. The first to fourth transfer gate electrodes TG1, TG2, TG3, and TG4 may, for example, overlap the second substrate 210 in the third direction Z.

In some embodiments, the first to fourth transfer gate electrodes TG1, TG2, TG3, and TG4 may be vertical transfer gates. For example, at least a portion of each of the first to fourth transfer gate electrodes TG1, TG2, TG3, and TG4 may be positioned inside the first substrate 110. For example, a trench extending from the first side 110a of the first substrate 110 may be formed in the first substrate 110. At least a portion of the first to fourth transfer gate electrodes TG1, TG2, TG3, and TG4 may be formed to fill the trench. Therefore, the lower surfaces of the first to fourth transfer gate electrodes TG1, TG2, TG3, and TG4 may be formed below the first side 110a of the first substrate 110 and the upper surfaces of the first to fourth transfer gate electrodes TG1, TG2, TG3, and TG4 may be disposed inside the first substrate 110.

In some embodiments, the widths of the first to fourth transfer gate electrodes TG1, TG2, TG3, and TG4 may decrease as they go away from the first side 110a of the first substrate 110. This may be due to the characteristics of the etching process for forming the trench.

The first wiring structure IS1 may be disposed on the first substrate 110. The first wiring structure IS1 may be disposed on the first side 110a of the first substrate 110. The first wiring structure IS1 may cover the first side 110a of the first substrate 110. The first semiconductor chip 100 may include a first substrate 110 and a first wiring structure IS1.

The first wiring structure IS1 may include a first inter-wiring insulating layer 195, a first wiring layer and a first bonding pad BP1 in the first inter-wiring insulating layer 195. The first wiring layer may include a plurality of first contacts 191 and 192, a plurality of first wirings 193, and a plurality of first vias 194. The number and placement of the first wiring layers, the placement of the first bonding pad BP1, and the like are merely examples, and embodiments of the present disclosure are not necessarily limited thereto.

A first contact 191 may connect the first to fourth transfer gate electrodes TG1, TG2, TG3 and TG4 and the first wiring 193 to each other. The first contact 192 may connect the floating diffusion region FD and the first wiring 193 to each other. The first via 194 may connect the first wiring 193 and the first bonding pad BP1 to each other.

One surface, such as a lower surface, of the first bonding pad BP1 may be exposed by the first inter-wiring insulating layer 195. A lower surface of the first bonding pad BP1 may be positioned on substantially the same plane (e.g., in the third direction Z) as the lower surface of the first inter-wiring insulating layer 195.

The second substrate 210 may include a fourth side 210b and a third side 210a that are opposite to each other (e.g, in the third direction Z). The third side 210a of the second substrate 210 may be a side that faces the first semiconductor chip 100. The third side 210a of the second substrate 210 may be opposite to the first side 110a of the first substrate 110 (e.g., in the third direction Z).

In an embodiment, the second substrate 210 may be bulk silicon or silicon on insulator (SOI). The second substrate 210 may be a silicon substrate or may include other substances, for example, silicon germanium, indium antimonide, lead tellurium compounds, indium arsenic, indium phosphide, gallium arsenide or gallium antimonide. However, embodiments of the present disclosure are not necessarily limited thereto. Alternatively, the second substrate 210 may have an epitaxial layer formed on a base substrate.

The second substrate 210 may include a plurality of regions P. In an embodiment, one region P may correspond to one pixel group PG. The dual conversion gain transistor DCX, the source follower transistor SX, the reset transistor RX, and the selection transistor AX included in one pixel group PG may be positioned in one region P.

A portion of the region P may overlap the first to fourth pixels PX1, PX2, PX3, and PX4 in the third direction Z. In an embodiment, the center of the region P may not be positioned on the same line in the third direction Z as the centers of the first to fourth pixels PX1, PX2, PX3, and PX4. For example, the region P may be biased in the first direction X relative to the first to fourth pixels PX1, PX2, PX3, and PX4. The region P may protrude from the first to fourth pixels PX1, PX2, PX3, and PX4 in the first direction X.

For example, the sum of the width of the region P in the first direction X and the distance between the regions P adjacent in the first direction X may be substantially equal to the sum of the width of the first pixel PX1 in the first direction X, the width of the second pixel PX2 in the first direction X, and the distance between the first pixel PX1 and the second pixel PX2.

The region P may be defined by a first portion 235a of a third-1 inter-wiring insulating layer 235, which will be described below. The first portion 235a of the third-1 inter-wiring insulating layer 235 may surround the region P from a planar viewpoint. For example, the first portion 235a of the third-1 inter-wiring insulating layer 235 may surround the region P in the X and Y directions. The first portion 235a of the third-1 inter-wiring insulating layer 235 may fill a through-hole 210h penetrating through the second substrate 210. The through-hole 210h may extend from the fourth side 210b of the second substrate 210 to the third side 210a.

The region P may include second active regions ACT21 and ACT22, third active regions ACT31 and ACT32, a second ground region GND2, and a third ground region GND3.

A second element isolation layer 212 and a third element isolation layer 214 may be further positioned inside the second substrate 210. The second element isolation layer 212 and the third element isolation layer 214 may be formed, for example, by burying an insulating material in a shallow trench formed by patterning the second substrate 210.

The second element isolation layer 212 may extend from the third side 210a of the second substrate 210 towards the fourth side 210b, and the bottom surface of the second element isolation layer 212 may be positioned in the second substrate 210. The second element isolation layer 212 may surround each of the second active regions ACT21 and ACT22 and the second ground region GND2. Accordingly, the second element isolation layer 212 may define the second active regions ACT21 and ACT22 and the second ground region GND2. The second active regions ACT21 and ACT22 and the second ground region GND2 may be spaced apart from each other.

The third element isolation layer 214 may extend from the fourth side 210b of the second substrate 210 towards the third side 210a, and the upper surface of the third element isolation layer 214 may be positioned in the second substrate 210. The third element isolation layer 214 may surround each of the third active regions ACT31 and ACT32. Accordingly, the third element isolation layer 214 may define the third active regions ACT31 and ACT32 and the third ground region GND3. The third active regions ACT31 and ACT32 and the third ground region GND3 may be spaced apart from each other.

In an embodiment, the second ground region GND2 and the third ground region GND3 may be formed by ion-implantation of high-concentration P-type impurities into the second substrate 210.

In an embodiment, the dual conversion gain transistor DCX and the source follower transistor SX may be positioned on the third side 210a of the second substrate 210. The entire dual conversion gain transistor DCX and the entire source follower transistor SX may overlap the second substrate 210 in the third direction Z. The dual conversion gain gate electrode DCG and the source follower gate electrode SF may be positioned on the third side 210a of the second substrate 210. The dual conversion gain gate electrode DCG may be positioned on the second active region ACT22 above the third side 210a of the second substrate 210, and the source follower gate electrode SF may be positioned on the second active region ACT22 above the third side 210a of the second substrate 210.

An impurity region 213 may be disposed in the second substrate 210. The impurity regions 213 may be positioned inside the third side 210a of the second substrate 210. The impurity region 213 may be formed by implanting impurities into the second substrate 210. The impurity region 213 may be positioned on one side of the dual conversion gain gate electrode DCG. The impurity region 213 may function as a source of the dual conversion gain transistor DCX.

The second wiring structure IS2 may be positioned on the second substrate 210. The second wiring structure IS2 may be positioned on the third side 210a of the second substrate 210. The second wiring structure IS2 may cover the third side 210a of the second substrate 210.

The second wiring structure IS2 may include a second inter-wiring insulating layer 225, a second wiring layer and a second bonding pad BP2 in the second inter-wiring insulating layer 225. The second wiring layer may include a plurality of second contacts 221a, 221b, 221c and 222, a plurality of second wirings 223, and a plurality of second vias 224. The number of layers and placement of the second wiring layer, the placement of the second bonding pads BP2, and the like shown in an embodiment of FIG. 8 are merely examples, and embodiments of the present disclosure are not necessarily limited thereto.

A second contact 221a may connect the dual conversion gain gate electrode DCG and the second wiring 223 to each other. A second contact 221b may connect the source follower gate electrode SF and the second wiring 223 to each other. A second contact 221c may connect the impurity region and the second wiring 223 in the active region (for example, the second active region ACT22) on one side of the dual conversion gain gate electrode DCG. The impurity region connected to the second contact 221c may serve as a drain of the dual conversion gain transistor DCX. The second contact 222 may connect the impurity region 213 and the second wiring 223. The second via 224 may connect the second wiring 223 and the second bonding pad BP2.

One surface, such as an upper surface, of the second bonding pad BP2 may be exposed by the second inter-wiring insulating layer 225. The upper surface of the second bonding pad BP2 may be positioned on substantially the same plane as the upper surface of the second inter-wiring insulating layer 225. The second bonding pad BP2 may be in direct contact with the first bonding pad BP1 exposed by the first inter-wiring insulating layer 195. The second inter-wiring insulating layer 225 may be in directly contact with the first inter-wiring insulating layer 195. The second bonding pad BP2 may be bonded to the first bonding pad BP1. Therefore, the second semiconductor chip 200 may be bonded to the first semiconductor chip 100.

The impurity region 213 and the source follower gate electrode SF may be electrically connected to the floating diffusion region FD through the first wiring structure IS1 and the second wiring structure IS2. For example, the floating diffusion region FD may be electrically connected to the first contact 191, the first wiring 193, the first via 194 and the first bonding pad BP1. The impurity region 213 may be electrically connected to the second contact 222, the second wiring 223, the second via 224, and the second bonding pad BP2. The source follower gate electrode SF may be electrically connected to the second contact 222b, the second wiring 223, the second via 224 and the second bonding pad BP2. The second bonding pad BP2 may be connected to the first bonding pad BP1, and the impurity region 213 and the source follower gate electrode SF may be electrically connected to the floating diffusion region FD accordingly.

The reset transistor RX and the selection transistor AX may be positioned on the fourth side 210b of the second substrate 210. The entire reset transistor RX and the entire selection transistor AX may overlap the second substrate 210 in the third direction Z. The reset gate electrode RG and the selection gate electrode SEL may be positioned on the fourth side 210b of the second substrate 210. In an embodiment, the reset gate electrode RG may be positioned on the third active region ACT31, and the selection gate electrode SEL may be positioned on the third active region ACT32.

A third wiring structure IS3 may be disposed on the second substrate 210. For example, the third wiring structure IS3 may be disposed on the fourth side 210b of the second substrate 210. The second wiring structure IS2 may cover the fourth side 210b of the second substrate 210. In an embodiment, the second semiconductor chip 200 may include a second substrate 210, a second wiring structure IS2, and a third wiring structure IS3.

The third wiring structure IS3 may include third inter-wiring insulating layers 235 and 236, and a third wiring layer and a third bonding pad BP3 in the third inter-wiring insulating layers 235 and 236. The third inter-wiring insulating layers 235 and 236 may include a third-1 inter-wiring insulating layer 235 and a third-2 inter-wiring insulating layer 236. The third wiring layer may include a plurality of third contacts 230, 231a, 231b, and 231c in the third-1 inter-wiring insulating layer 235, and a plurality of third wirings 233, a plurality of third vias 234 and a third bonding pad BP3 in the third-2 inter-wiring insulating layer 236. The number of layers and placement of the third wiring layer, the placement of the third bonding pad BP3, and the like shown in an embodiment of FIG. 8 are merely examples, and embodiments of the present disclosure are not necessarily limited thereto.

The third-1 inter-wiring insulating layer 235 may include a first portion 235a and a second portion 235b. The first portion 235a may fill the through-hole 210h of the second substrate 210, and the second portion 235b may be disposed on the fourth side 210b of the second substrate 210 and the first portion 235a. The second portion 235b may cover the fourth side 210b of the second substrate 210. The third-2 inter-wiring insulating layer 236 may be disposed on the third-1 inter-wiring insulating layer 235. For example, the third-2 inter-wiring insulating layer 236 may be disposed directly on a lower surface of the third-1 inter-wiring insulating layer 235.

The third contact 230 may be positioned inside the through-hole 210h. The third contact 230 may partially penetrate the third-1 inter-wiring insulating layer 235 and the second inter-wiring insulating layer 225 to connect the third wiring 233 and the second wiring 223 to each other. The third contact 231a may connect the reset gate electrode RG and the third wiring 233 to each other. The third contact 231b may connect the selection gate electrode SEL and the third wiring 233 to each other. The third contact 231c may connect the impurity region and the third wiring 233 in the active region (e.g., the third active region ACT31) on one side of the reset gate electrode RG. The impurity region connected to the third contact 231c may serve as the source of the reset transistor RX. The source of the reset transistor RX may be connected to the drain of the dual conversion gain transistor DCX through the third contact 231c, the third wiring 233, the third contact 230, the second wiring 223 and the second contact 221c. The third via 234 may connect the third wiring 233 and the third bonding pad BP3.

One surface, such as a lower surface, of the third bonding pad BP3 may be exposed by the third-2 inter-wiring insulating layer 236. The lower surface of the third bonding pad BP3 may be positioned on substantially the same plane as the lower surface of the third-2 inter-wiring insulating layer 236.

The third substrate 310 may include a fifth side 310a that faces the second semiconductor chip 200. The fifth side 310a of the third substrate 310 may be opposite to the fourth side 210b of the second substrate 210 (e.g., in the third direction Z).

An impurity region that serves as a drain of the dual conversion gain transistor DCX may be positioned on one side of the dual conversion gain gate electrode DCG in the second substrate 210, and an impurity region that serves as the source of the reset transistor RX may be positioned on one side of the reset gate electrode RG in the second substrate 210. The impurity region positioned on one side of the dual conversion gain gate electrode DCG may be connected to the impurity region positioned on one side of the reset gate electrode RG through the second wiring structure IS2 and the third wiring structure IS3. An impurity region that serves as the source of the source follower transistor SX may be positioned on one side of the source follower gate electrode SF in the second substrate 210, and an impurity region that serves as the drain of the selection transistor SEL may be positioned on one side of the selection gate electrode SEL in the second substrate 210. The impurity region positioned on one side of the source follower transistor SX may be connected to the impurity region positioned on one side of the selection gate electrode SEL through the second wiring structure IS2 and the third wiring structure IS3.

In an embodiment, the third substrate 310 may be bulk silicon or silicon on insulator (SOI). For example, the third substrate 310 may be a silicon substrate or may include other substances, for example, silicon germanium, indium antimonide, lead tellurium compounds, indium arsenic, indium phosphide, gallium arsenide or gallium antimonide. However, embodiments of the present disclosure are not necessarily limited thereto. Alternatively, the second substrate 210 may have an epitaxial layer formed on a base substrate

A transistor including the gate electrode 312 may be positioned on the fifth side 310a of the third substrate 310. In an embodiment, the transistor including the gate electrode 312 may include, for example, electronic elements that constitute the control register block 11, the timing generator 12, the ramp signal generator 13, the row driver 14, the readout circuit 16, and the like of FIG. 1.

A fourth wiring structure IS4 may be disposed on the third substrate 310. The fourth wiring structure IS4 may be disposed on the fifth side 310a of the third substrate 310. The fourth wiring structure IS4 may cover the fifth side 510a of the third substrate 310. In an embodiment, the third semiconductor chip 300 may include a third substrate 310 and a fourth wiring structure IS4.

The fourth wiring structure IS4 may include a fourth inter-wiring insulating layer 325, and a fourth wiring layer and a fourth bonding pad BP4 in the fourth inter-wiring insulating layer 325. The fourth wiring layer may include a plurality of fourth contacts 321, a plurality of fourth wirings 323 and a plurality of fourth vias 324. The number of layers and placement of the fourth wiring layer, the positioning of the fourth bonding pads BP4, and the like shown in an embodiment of FIG. 8 are merely examples, and embodiments of the present disclosure are not necessarily limited thereto.

A fourth contact 321 may connect the gate electrode 312 and the fourth wiring 323 to each other. The fourth via 324 may connect the fourth wiring 323 and the fourth bonding pad BP4 to each other.

One surface, such as an upper surface, of the fourth bonding pad BP4 may be exposed by the fourth inter-wiring insulating layer 325. The upper surface of the fourth bonding pad BP4 may be positioned on substantially the same plane as the upper surface of the fourth inter-wiring insulating layer 325. The fourth bonding pad BP4 may be in direct contact with the third bonding pad BP3. The fourth inter-wiring insulating layer 325 may be in direct contact with the third-2 inter-wiring insulating layer 236. The fourth bonding pad BP4 may be bonded to the third bonding pad BP3. Therefore, the third semiconductor chip 300 may be bonded to the second semiconductor chip 200.

In an embodiment, the first inter-wiring insulating layer 195, the second inter-wiring insulating layer 225, the third-1 inter-wiring insulating layer 235, the third-2 inter-wiring insulating layer 236, and the fourth inter-wiring insulating layer 325 may each include, for example, at least one of silicon oxide, silicon nitride, silicon oxynitride, and a low dielectric constant (low-k) material having a dielectric constant lower than that of silicon oxide. However, embodiments of the present disclosure are not necessarily limited thereto.

In an embodiment, a plurality of first contacts 191 and 192, a plurality of first wirings 193, a plurality of first vias 194, a first bonding pad BP1, a plurality of second contacts 221a, 221b, 221c, and 220, a plurality of second wirings 223, a plurality of second vias 226, a plurality of second bonding pads BP2, a plurality of third contacts 231 and 232, a plurality of third wirings 233, a plurality of third vias 234, a third bonding pad BP3, a plurality of fourth contacts 321, a plurality of fourth wirings 323, a plurality of fourth vias 324, and a fourth bonding pads BP4 may each include, for example, at least one of tungsten (W), copper (Cu), aluminum (Al), gold (Au), silver (Ag), and alloys thereof. However, embodiments of the present disclosure are not necessarily limited thereto. For example, the first bonding pad BP1 and the second bonding pad BP2, and the third bonding pad BP3 and the fourth bonding pad BP4 may each include the same material.

A gate dielectric layer 132 may be disposed between the first substrate 110 and the first to fourth transfer gate electrodes TG1, TG2, TG3 and TG4. The gate dielectric layer 132 may be disposed between the second substrate 210 and the dual conversion gain gate electrode DCG, and between the second substrate 210 and the source follower gate electrode SF. The gate dielectric layer 132 may be disposed between the second substrate 210 and the reset gate electrode RG, and between the second substrate 210 and the selection gate electrode SEL. The gate dielectric layer 132 may be disposed between the third substrate 310 and the gate electrode 312.

In an embodiment, the gate dielectric layer 132 may include, for example, at least one of silicon oxide, silicon nitride, silicon oxynitride, and a low dielectric constant (low-k) material having a dielectric constant lower than that of silicon oxide. However, embodiments of the present disclosure are not necessarily limited thereto.

A gate spacer 134 may be positioned on each side surface of the first to fourth transfer gate electrodes TG1, TG2, TG3 and TG4, the dual conversion gain gate electrode DCG, the source follower gate electrode SF, the reset gate electrode RG, and the selection gate electrode SEL.

The first insulating layer 140 may be disposed on the second side 110b of the first substrate 110. The first insulating layer 140 may extend along the second side 110b of the first substrate 110. In some embodiments, at least a portion of the first insulating layer 140 may be in direct contact with the pixel isolation pattern 120.

The first insulating layer 140 may include an insulating material. For example, in an embodiment the first insulating layer 140 may include at least one of silicon oxide, silicon nitride, silicon oxynitride, aluminum oxide, hafnium oxide, and combinations thereof. However, embodiments of the present disclosure are not necessarily limited thereto.

The color filter 170 may be disposed on the first insulating layer 140. The color filter 170 may be arranged to correspond to each of the first to fourth pixels PX1, PX2, PX3, and PX4. For example, the plurality of color filters 170 may be arranged two-dimensionally (e.g., in the form of a matrix) in a plane that includes the first direction X and the second direction Y.

For example, in an embodiment the color filter 170 may be arranged in a Bayer pattern that includes a red color filter, a green color filter, and a blue color filter. As another example, the color filter 170 may include a yellow filter, a magenta filter, and a cyan filter, and may further include a white filter. However, embodiments of the present disclosure are not necessarily limited thereto and the arrangement of the color filter 170 may further vary.

A grid pattern 150 may be positioned between the color filters 170. The grid pattern 150 may be positioned on the first insulating layer 140. The grid pattern 150 may be formed in a grid pattern from a planar viewpoint and may be interposed between the color filters 170.

In an embodiment, the grid pattern 150 may include a conductive pattern 151 and a low refractive index pattern 153. The conductive pattern 151 and the low refractive index pattern 153 may be, for example, sequentially stacked on the first insulating layer 140.

The conductive pattern 151 may include a conductive material. For example, in an embodiment the conductive pattern 151 may include at least one of titanium (Ti), titanium nitride (TIN), tantalum (Ta), tantalum nitride (TaN), tungsten (W), aluminum (Al), copper (Cu), and combinations thereof. The low refractive index pattern 153 may include a low refractive index material having a lower refractive index than silicon (Si). For example, the low refractive index pattern 153 may include at least one compound selected from silicon oxide, aluminum oxide, tantalum oxide, and combinations thereof.

A first protective layer 155 may be disposed on the first insulating layer 140 and the grid pattern 150. For example, the first protective layer 155 may conformally extend along profiles of the upper surface of the first insulating layer 140 and the side and upper surfaces of the grid pattern 150. In an embodiment, the first protective layer 155 may include, for example, aluminum oxide.

A second insulating layer 160 may be disposed on the color filter 170. The second insulating layer 160 may cover the color filter 170. The second insulating layer 160 may include an insulating material. For example, in an embodiment the second insulating layer 160 may include silicon oxide.

A microlens 180 may be disposed on the second insulating layer 160. In an embodiment, the microlens 180 may be arranged to correspond to each of the first to fourth pixels PX1, PX2, PX3, and PX4. For example, the plurality of microlenses 180 may be arranged two-dimensionally (e.g., in the form of a matrix) in a plane including the first direction X and the second direction Y.

A second protective layer 185 may be disposed on the microlenses 180. The second protective layer 185 may extend along the surface of the microlens 180. The second protective layer 185 may include, for example, an inorganic oxide layer. For example, in an embodiment the second protective layer 185 may include at least one of silicon oxide, titanium oxide, zirconium oxide, hafnium oxide, and combinations thereof. However, embodiments of the present disclosure are not necessarily limited thereto. The second protective layer 185 may include, for example, low temperature oxide (LTO).

In the image sensor according to some embodiments, the dual conversion gain transistor DCX, the source follower transistor SX, the reset transistor RX, and the selection transistor AX may be disposed on the fourth side 210b and the third side 210a of the second substrate 210. For example, the dual conversion gain transistor DCX, the source follower transistor SX, the reset transistor RX, and the selection transistor AX may be formed, using both sides of the second substrate 210 without an additional substrate. In addition, since both sides of the second substrate 210 are used, an area in which the transistors DCX, SX, RX, and AX are formed may increase as compared to an embodiment in which the transistors DCX. SX, RX, and AX are formed on one side of the second substrate 210. Also, since both sides of the second substrate 210 are used, the size of the image sensor may decrease as compared to an embodiment in which the transistors DCX, SX, RX, and AX are formed on one side of the second substrate 210.

In the image sensor according to some embodiments, since the pixel groups PG share the floating diffusion region FD, the area of the floating diffusion region FD may increase.

In the image sensor according to some embodiments, the first to third semiconductor chips 100, 200, and 300 may be bonded by the first to fourth bonding pads BP1, BP2, BP3, and BP4. Therefore, for example, compared to an embodiment in which the first to third semiconductor chips 100, 200, and 300 are bonded by the use of a deep contact extending from the first substrate 110 to the second substrate 210, the degree of freedom in design in which the transistors and the like are positioned on the second substrate 210 may increase.

Further, for example, in an embodiment in which the floating diffusion region FD of the first substrate 110, and the dual conversion gain transistor DCX and the source follower transistor SX of the second substrate 210 are connected using the deep contact extending from the first substrate 110 to the second substrate 210, the parasitic capacitance may increase due to the length of the dip contact, and the conversion gain may decrease accordingly. However, in the image sensor according to some embodiments of the present disclosure, the dual conversion gain transistor DCX and the source follower transistor SX are positioned on the third side 210a of the second substrate 210 and connected by the first and second wiring structures IS1 and IS2. Therefore, the parasitic capacitance may decrease, and the conversion gain may increase accordingly.

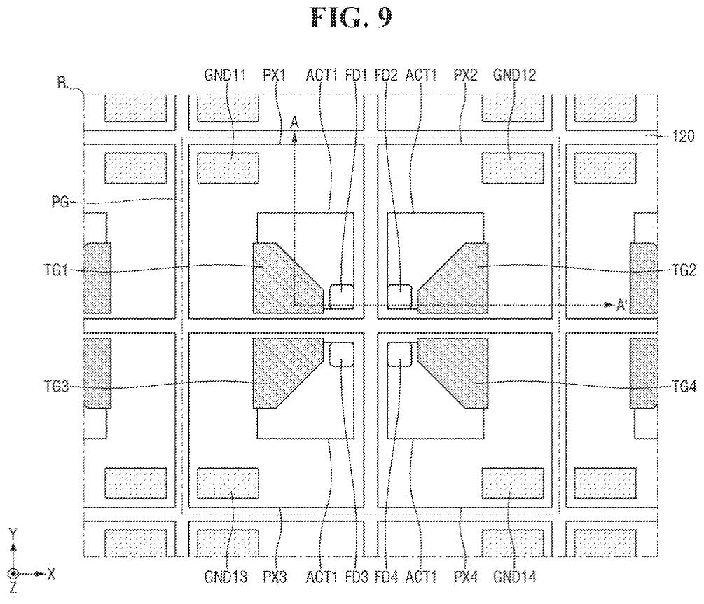

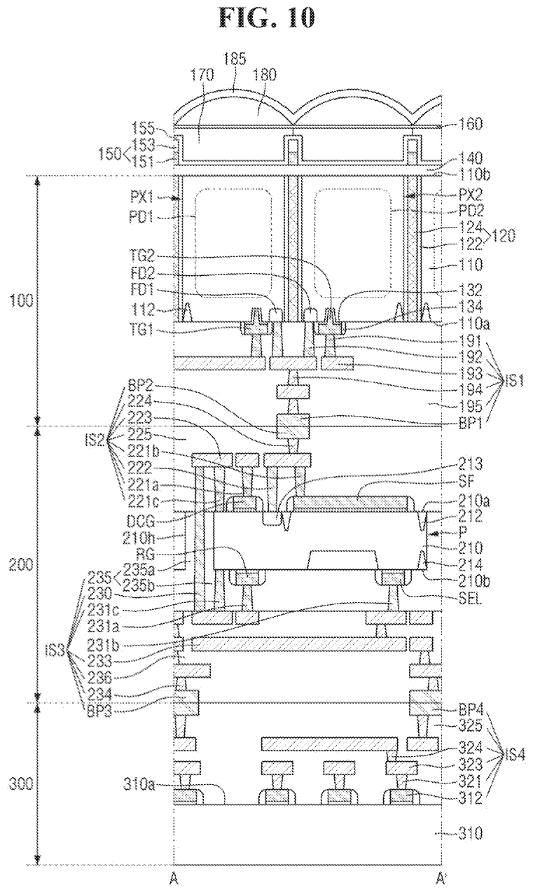

FIG. 9 is an enlarged view of the region R of FIG. 4. FIG. 10 is a cross-sectional view taken along a line A-A′ of FIG. 9. For convenience of explanation, the explanation will focus on points that are different from those explained using FIGS. 1 to 8 and a repeated description of similar or identical elements may be omitted for economy of description.

Referring to FIGS. 9 and 10, in the image sensor according to some embodiments, the first to fourth pixels PX1, PX2, PX3 and PX4 in the pixel group PG may include first to fourth floating diffusion regions FD1, FD2, FD3, and FD4, respectively.

The first to fourth floating diffusion regions FD1, FD2, FD3 and FD4 may be connected to the impurity region 213 of the second substrate 210 through the first wiring structure IS1. The first contact 192 may connect the first floating diffusion region FD1 and the first wiring 193, and the first contact 192 may connect the second floating diffusion region FD2 and the first wiring 193

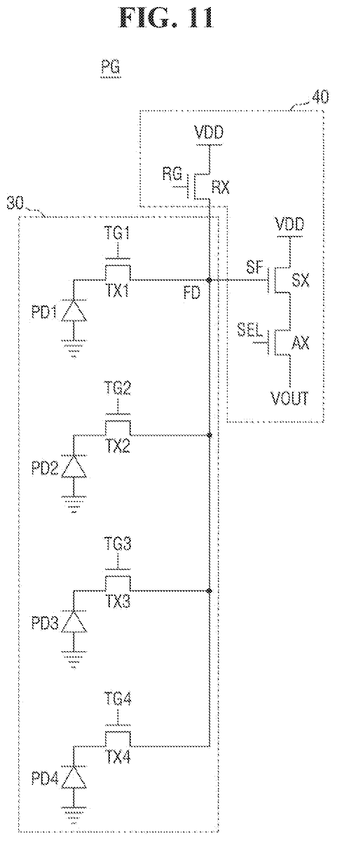

FIG. 11 is a circuit diagram for explaining pixel of an image sensor according to some embodiments.

Referring to FIG. 11, a pixel group PG of an image sensor according to some embodiments may include first to fourth photoelectric conversion elements PD1, PD2, PD3, PD4, a floating diffusion region FD, a reset transistor RX, a source follower transistor SX, and a selection transistor AX. The first to fourth photoelectric conversion elements PD1, PD2, PD3, PD4 may share the floating diffusion region FD, the reset transistor RX, the source follower transistor SX and the selection transistor AX.

A source of the reset transistor RX may be connected to the floating diffusion region FD.

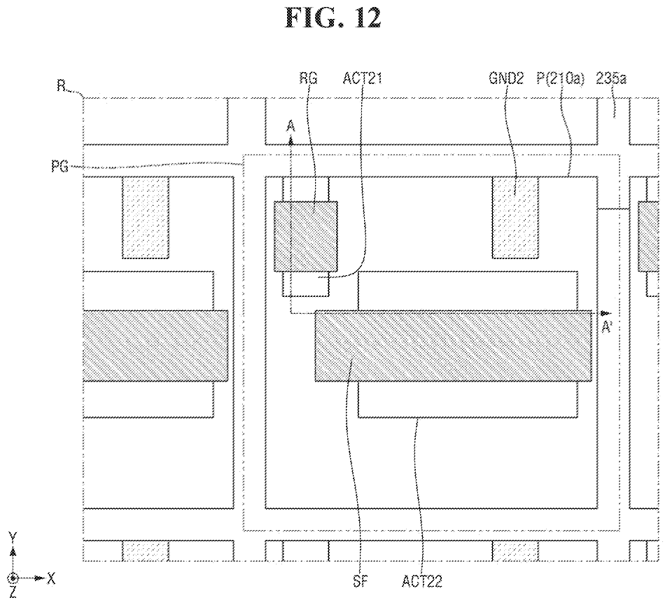

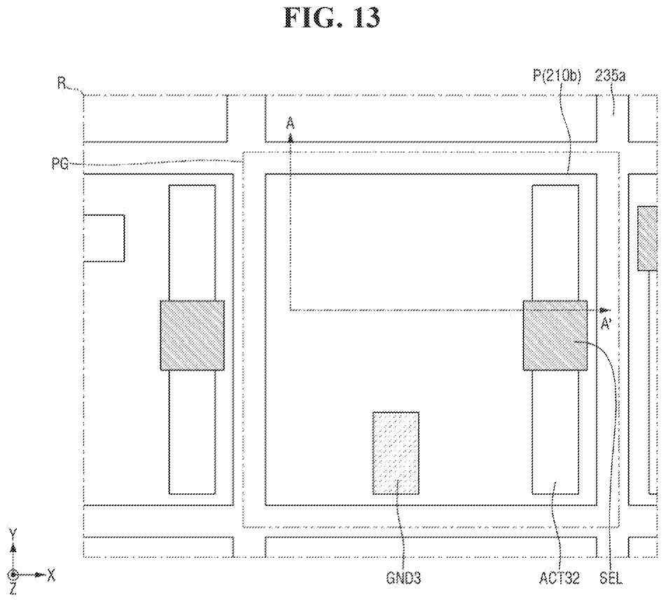

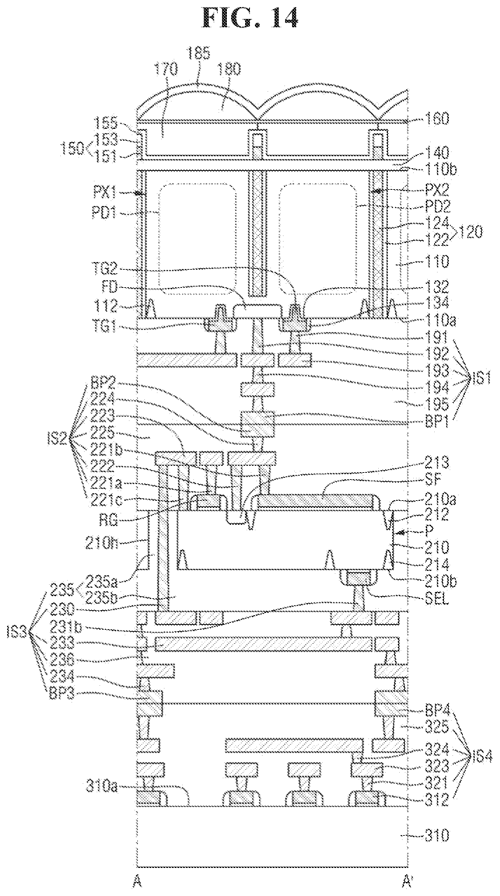

FIGS. 12 and 13 are enlarged views of the region R of FIG. 4. FIG. 12 is an enlarged view of the region R on the third side 210a of the second substrate 210 of the second semiconductor chip 200, and FIG. 13 is an enlarged view of the region R on the fourth side 210b of the second substrate 210 of the second semiconductor chip 200. FIG. 14 is a cross-sectional view taken along a line A-A′ of FIGS. 5, 12 and 13.

Referring to FIGS. 11 to 14, the source follower transistor SX, the reset transistor RX, and the selection transistor AX included in one pixel group PG may be positioned in one region P. In an embodiment, the region P may include second active regions ACT21 and ACT22, a third active region ACT32, a second ground region GND2, and a third ground region GND3.

The reset transistor RX and the source follower transistor SX may be disposed on the third side 210a of the second substrate 210. The entire reset transistor RX and the entire source follower transistor SX may overlap the second substrate 210 in the third direction Z. The reset gate electrode RG and the source follower gate electrode SF may be disposed on the third side 210a of the second substrate 210. In an embodiment, the reset gate electrode RG may be disposed on the second active region ACT22 on the third side 210a of the second substrate 210, and the source follower gate electrode SF may be disposed on the second active region ACT22 on the third side 210a of the second substrate 210.

The selection transistor AX may be disposed on the fourth side 210b of the second substrate 210. The entire selection transistor AX may overlap the second substrate 210 in the third direction Z. The selection gate electrode SEL may be disposed on the fourth side 210b of the second substrate 210. The selection gate electrode SEL may be disposed on the third active region ACT32.

The impurity region 213 may be positioned on one side of the reset gate electrode RG. The impurity region 213 may serve as the source of the reset transistor RX.

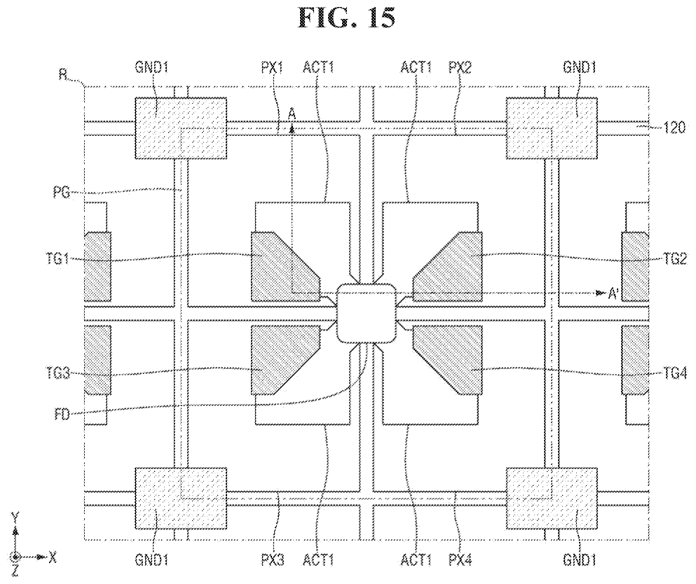

FIG. 15 is an enlarged view of the region R of FIG. 4.

Referring to FIG. 15, four pixels PX1, PX2, PX3, and PX4 adjacent to each other in the image sensor according to some embodiments may share the first ground region GND1. The first ground region GND1 may be positioned between four different pixel groups PG, and the four pixels PX1, PX2, PX3, and PX4 adjacent to the first ground region GND1 in each of the four pixel groups PG may share the first ground region GND1. In an embodiment, the first to fourth pixels PX1, PX2, PX3, and PX4 that share the first ground region GND1 may be included in different pixel groups PG. For example, the plurality of pixel groups PG may include a first pixel group, a second pixel group adjacent to the first pixel group in the first direction X, a third pixel group adjacent to the first pixel group in the second direction Y, and a fourth pixel group adjacent to the third pixel group in the first direction X and adjacent to the second pixel group in the second direction Y. The first ground region GND1 may be positioned between the first to fourth pixel groups. The fourth pixel PX4 of the first pixel group, the third pixel PX3 of the second pixel group, the second pixel PX2 of the third pixel group, and the first pixel PX1 of the fourth pixel group may share the first ground region GND1.

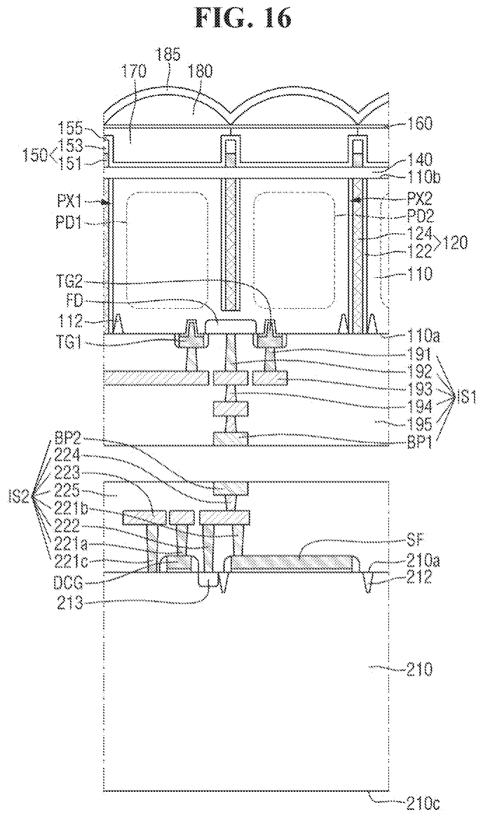

FIGS. 16 to 19 are intermediate stage diagrams for explaining a method for manufacturing an image sensor according to some embodiments. The first and second pixels PX1 and PX2 will be described as an example.

Referring to FIG. 16, the pixel isolation pattern 120 may be formed in the first substrate 110. The first and second pixels PX1 and PX2 may be separated by the pixel isolation pattern 120. A plurality of active regions (e.g., the first active region ACT1 and the first ground region GND1) separated by the first element isolation layer 112 may be formed in the first substrate 110. The floating diffusion region FD may be formed in the first substrate 110. First and second photoelectric conversion elements PD1 and PD2 may be formed in the first substrate 110.

In an embodiment, the first transfer transistor TX1 including the first transfer gate electrode TG1 and the second transfer transistor TX2 including the second transfer gate electrode TG2 may be formed on the first side 110a of the first substrate 110. The first wiring structure IS1 may be formed on (e.g., formed directly below) the first side 110a of the first substrate 110. The first wiring structure IS1 may include a first inter-wiring insulating layer 195, and a plurality of first contacts 191 and 192, a plurality of first wirings 193, a plurality of first vias 194, and a first bonding pad BP1 inside the first inter-wiring insulating layer 195. For example, in an embodiment the width of the plurality of first contacts 191 and 192 and the width of the plurality of first vias 194 may become smaller as they approach the first side 110a of the first substrate 110.

In an embodiment, the first insulating layer 140, the grid pattern 150, the first protective layer 155, the second insulating layer 160, the microlens 180 and the second protective layer 185 may be formed on the second side 110b of the first substrate 110.

The second substrate 210 that includes a sixth side 210c and a third side 210a opposite to each other (e.g., in the third direction Z) may be provided. A plurality of active regions (e.g., the second active regions ACT21 and ACT22 and the second ground region GND2) separated by the second element isolation layer 212 may be formed in the fourth side 210b of the second substrate 210. In an embodiment, the dual conversion gain transistor DCX including the dual conversion gain gate electrode DCG and the source follower transistor SX including the source follower gate electrode SF may be formed on the third side 210a of the second substrate 210.

The second wiring structure IS2 may be formed on the third side 210a of the second substrate 210. The second wiring structure IS2 may include the second inter-wiring insulating layer 225, and the plurality of second contacts 221a, 221b, 221c, and 222, the plurality of second wirings 223, the plurality of second vias 224 and the second bonding pad BP2 inside the second inter-wiring insulating layer 225. For example, in an embodiment the widths of the plurality of second contacts 221a, 221b, 221c, and 222 and the widths of the plurality of second vias 224 may decrease as they approach the third side 210a of the second substrate 210.

Subsequently, the first bonding pad BP1 and the second bonding pad BP2 may come into direct contact with each other. The first bonding pad BP1 and the second bonding pad BP2 may be bonded. Therefore, the second wiring structure IS2 and the first wiring structure IS1 may be bonded.

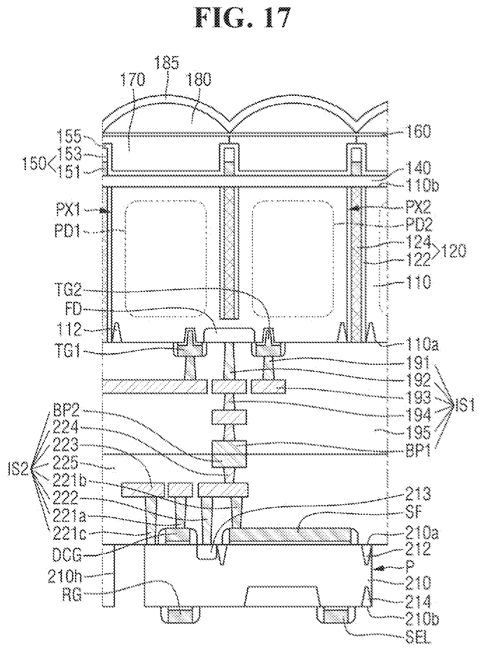

Referring to FIG. 17, the sixth side 210c of the second substrate 210 may be ground. Accordingly, the second substrate 210 may include the fourth side 210b and the third side 210a that are opposite to each other (e.g., in the third direction Z).

Subsequently, a plurality of active regions (e.g., the third active regions ACT31 and ACT32 and the third ground region GND3) separated by the third element isolation layer 214 may be formed in the fourth side 210b of the second substrate 210. The reset transistor RX including the reset gate electrode RG and the selection transistor AX including the selection gate electrode SEL may be formed on the fourth side 210b of the second substrate 210. A through-hole 210h may be formed in the second substrate 210. The region P of the second substrate 210 may be defined by the through-hole 210h.

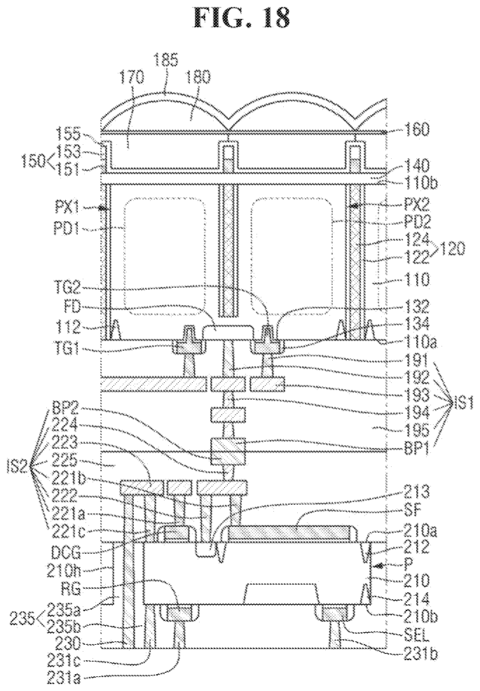

Referring to FIG. 18, a third-1 inter-wiring insulating layer 235 may be formed on the fourth side 210b of the second substrate 210. The first portion 235a of the third-1 inter-wiring insulating layer 235 may fill the through-hole 210h, and the second portion 235b of the third-1 inter-wiring insulating layer 235 may cover the fourth side 210b of the second substrate 210. The region P of the second substrate 210 may be defined by the first portion 235a of the third-1 inter-wiring insulating layer 235.

Subsequently, a plurality of third contacts 230, 231a, 231b, and 231c may be formed. The third contact 230 may partially penetrate the third-1 inter-wiring insulating layer 235 and the second inter-wiring insulating layer 225 in the through-hole 210h, and may be connected to the second wiring 223. The third contact 231a may penetrate the third-1 inter-wiring insulating layer 235 and be connected to the reset gate electrode RG, and the third contact 231b may penetrate the third-1 inter-wiring insulating layer 235 and be connected to the selection gate electrode SEL. The third contact 231c may penetrate the third-1 inter-wiring insulating layer 235 and be connected to the impurity region in the active region (for example, the third active region ACT31) on one side of the reset gate electrode RG. In an embodiment, the impurity region connected to the third contact 231c may serve as the source of the reset transistor RX.

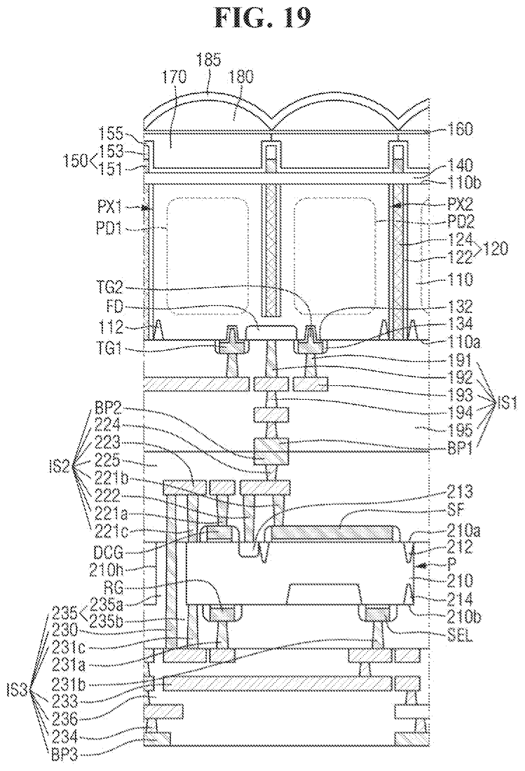

Referring to FIG. 19, the third-2 inter-wiring insulating layer 236, the plurality of third wirings 233, the plurality of third vias 234, and the third bonding pad BP3 may be formed on the third-1 inter-wiring insulating layer 235. Therefore, the third wiring structure IS3 may be formed.

Although embodiments of the present disclosure have been described above with reference to the accompanying drawings, the present disclosure is not limited to the above embodiments, and may be manufactured in various forms. Those skilled in the art will appreciate that the present disclosure may be embodied in other specific forms without changing the technical spirit or essential features of the present disclosure. Accordingly, the above-described embodiments are to be considered in all respects as illustrative and not restrictive.

What is claimed is:

1. An image sensor comprising:
a first substrate that includes a first side and a second side opposite to each other in a first direction;
a photoelectric conversion element in the first substrate;
a first gate electrode on the first side of the first substrate and positioned adjacent to the photoelectric conversion element;
a floating diffusion region in the first substrate on one side of the first gate electrode;
a first wiring structure on the first side of the first substrate, the first wiring structure including a first wiring layer and a first bonding pad on the first wiring layer;
a second substrate that includes a third side opposite to the first side and a fourth side opposite to the third side;
second and third gate electrodes spaced apart from each other on the third side of the second substrate;
an impurity region in the second substrate on one side of the second gate electrode;
a second wiring structure on the third side of the second substrate, the second wiring structure including a second wiring layer and a second bonding pad on the second wiring layer;
a fourth gate electrode on the fourth side of the second substrate; and
a third wiring structure on the fourth side of the second substrate, the third wiring structure including a third wiring layer
wherein the second bonding pad directly contacts the first bonding pad, and
the floating diffusion region is connected to the impurity region through the first wiring structure and the second wiring structure.

2. The image sensor of claim 1, further comprising:
a fifth gate electrode on the fourth side of the second substrate, the fifth gate electrode is spaced apart from the fourth gate electrode

3. The image sensor of claim 1, further comprising:
a pixel isolation pattern in the first substrate, the pixel isolation pattern separates a first pixel and a second pixel from each other,
wherein each of the first pixel and the second pixel includes the photoelectric conversion element, the first gate electrode and the floating diffusion region, and
the floating diffusion region of the first pixel is connected to the floating diffusion region of the second pixel through the first wiring structure.

4. The image sensor of claim 1, further comprising:
a pixel isolation pattern that extends from the second side of the first substrate in the first direction and separates a first pixel and a second pixel from each other,
wherein each of the first pixel and the second pixel includes the photoelectric conversion element and the first gate electrode,
the floating diffusion region is positioned between the first gate electrode of the first pixel and the first gate electrode of the second pixel, and
the pixel isolation pattern is spaced apart from the floating diffusion region in the first direction.

5. The image sensor of claim 1, wherein the second wiring structure further includes:
an inter-wiring insulating layer defining a region of the second substrate inside the second substrate; and
a contact penetrating the inter-wiring insulating layer and connecting the second wiring layer and the third wiring layer to each other,
wherein the fourth gate electrode is disposed on the region of the second substrate.

6. The image sensor of claim 1,
wherein the floating diffusion region overlaps the second substrate in the first direction.

7. The image sensor of claim 1,
wherein the first gate electrode overlaps the second substrate in the first direction.

8. The image sensor of claim 1, wherein:
the third wiring structure further includes a third bonding pad on the third wiring layer; and
the image sensor further comprises:
a third substrate including a fifth side opposite to the fourth side;
a fifth gate electrode disposed on the fifth side of the third substrate; and
a fourth wiring structure that includes a fourth wiring layer and a fourth bonding pad on the fifth side of the third substrate, the fourth bonding pad directly contacting the third bonding pad.

9. The image sensor of claim 1,
wherein at least a portion of the first gate electrode is positioned inside the first substrate.

10. The image sensor of claim 1,
wherein the third gate electrode is connected to the floating diffusion region through the first wiring structure and the second wiring structure.

11. An image sensor comprising:
a first semiconductor chip and a second semiconductor chip having a plurality of pixel groups positioned therein, the first and second semiconductor chips are stacked in a first direction,
wherein the first semiconductor chip includes:
a first substrate that includes a first side and a second side opposite to each other in the first direction;
a first pixel on the first side of the first substrate, the first pixel including a first photoelectric conversion element in the first substrate and a first-1 transistor;
a second pixel on the first side of the first substrate, the second pixel including a second photoelectric conversion element in the first substrate and a first-2 transistor;
a third pixel on the first side of the first substrate, the third pixel including a third photoelectric conversion element in the first substrate and a first-3 transistor;
a fourth pixel on the first side of the first substrate, the fourth pixel including a fourth photoelectric conversion element in the first substrate and a first-4 transistor;
a floating diffusion region connected to the first-1 to first-4 transistors in the first substrate, the floating diffusion region is disposed between the first to fourth pixels; and
a first wiring structure on the first side of the first substrate, the first wiring structure including a first wiring layer,
wherein the second semiconductor chip includes:
a second substrate including a third side opposite to the first side, and a fourth side opposite to the third side;
a second wiring structure on the third side of the second substrate, the second wiring structure including a second wiring layer;
second and third transistors on the third side of the second substrate, the second and third transistors are spaced apart from each other;
a fourth transistor on the fourth side of the second substrate; and
a third wiring structure on the fourth side of the second substrate, the third wiring structure including a third wiring layer,
wherein each plurality of pixel groups includes the first to fourth pixels, the floating diffusion region, and the second to fourth transistors.

12. The image sensor of claim 11, wherein:
the first wiring structure includes a first bonding pad on the first wiring layer;
the second wiring structure includes a second bonding pad on the second wiring layer; and
the first bonding pad directly contacts the second bonding pad.

13. The image sensor of claim 11, wherein:
the first pixel further includes a first ground region in the first substrate,
the second pixel further includes a second ground region in the first substrate,
the third pixel further includes a third ground region in the first substrate, and
the fourth pixel further includes a fourth ground region in the first substrate.

14. The image sensor of claim 11, wherein:
the plurality of pixel groups include first to fourth pixel groups;
the image sensor further includes a ground region inside the first substrate between the first to fourth pixel groups; and
pixels adjacent to the ground region in each of the first to fourth pixel groups share the ground region.

15. The image sensor of claim 11, further comprising:
a pixel isolation pattern inside the first substrate, the pixel isolation pattern separating the first to fourth pixels;
the second substrate includes a region that the second to fourth transistors are positioned therein;
the second wiring structure further includes an inter-wiring insulating layer that fills a through-hole penetrating the second substrate, the inter-wiring insulating layer defines the region of the second substrate; and
the pixel isolation pattern and the inter-wiring insulating layer do not overlap each other in the first direction.

16. The image sensor of claim 11, wherein:
the second transistor and the third transistor are connected to the floating diffusion region through the first wiring structure; and
the fourth transistor is connected to the third transistor through the first wiring structure and the second wiring structure.

17. The image sensor of claim 11, further comprising:
a fifth transistor on the fourth side of the second substrate, the fifth transistor is connected to the second transistor through the second wiring structure,
wherein each of the plurality of pixel groups further includes the fifth transistor.

18. The image sensor of claim 11, wherein:
the second substrate includes a region that the second to fourth transistors are positioned therein;
the second wiring structure includes an inter-wiring insulating layer that fills a through-hole penetrating the second substrate, the inter-wiring insulating layer defines the region of the second substrate and a contact in the through-hole that connects the first wiring layer and the second wiring structure to each other; and
the fourth transistor is connected to the second transistor through the second wiring structure and the third wiring structure.

19. An image sensor comprising:
a first substrate that includes a first side and a second side opposite to each other in a first direction;
a color filter on the second side of the first substrate;
a microlens on the color filter;
a photoelectric conversion element inside the first substrate;
a first gate electrode on the first side of the first substrate, the first gate electrode is positioned adjacent to the photoelectric conversion element;
a floating diffusion region in the first substrate on one side of the first gate electrode;
a first wiring structure on the first side of the first substrate, the first wiring structure including a first wiring layer and a first bonding pad on the first wiring layer;
a second substrate that includes a third side opposite to the first side and a fourth side opposite to the third side;
second and third gate electrodes on the third side of the second substrate, the second and third gate electrodes are spaced apart from each other;
an impurity region inside the second substrate on one side of the second gate electrode;
a second wiring structure on the third side of the second substrate, the second wiring structure including a second wiring layer and a second bonding pad on the second wiring layer, the second bonding pad directly contacting the first bonding pad;
a fourth gate electrode on the fourth side of the second substrate;
a third wiring structure on the fourth side of the second substrate, the third wiring structure including a third wiring layer, a contact penetrating the second substrate and connected to the second wiring layer and the third wiring layer, and a third bonding pad on the third wiring layer;
a third substrate including a fifth side opposite to the fourth side;
a fifth gate electrode on the fifth side of the third substrate; and
a fourth wiring structure on the fifth side of the third substrate, the fourth wiring structure including a fourth wiring layer and a fourth bonding pad on the fourth wiring layer,
wherein the first bonding pad directly contacts the second bonding pad,
the third bonding pad directly contacts the fourth bonding pad, and
the floating diffusion region is connected to the impurity region and the third gate electrode through the first wiring structure and the second wiring structure.

20. The image sensor of claim 19, further comprising:
a sixth gate electrode on the fourth side of the second substrate.
